(19) United States
(12) Patent Application Publication
(10) Pub. No.: US 2025/0212536 A1
(43) Pub. Date: Jun. 26, 2025

(54) IMAGE SENSOR WITH LIGHT BALANCING STRUCTURE AND METHODS THEREOF

(71) Applicant: OMNIVISION TECHNOLOGIES, INC., Santa Clara, CA (US)

(72) Inventors: Yuanwei Zheng, San Jose, CA (US); Chao Niu, Santa Clara, CA (US)

(21) Appl. No.: 18/391,236

(22) Filed: Dec. 20, 2023

(51) Int. Cl. H01L 27/146

(52) U.S. Cl. CPC H10F 39/802; H10F 39/182; H10F 39/8037; H10F 39/8057; H10F 39/811

(57) ABSTRACT

An image sensor is described. The image sensor includes a plurality of pixel cells arranged to form an image sensor array disposed in or on a semiconductor substrate, a proximal metal layer, and a light balancing structure. Each pixel cell included in the plurality of pixel cells includes one or more photodiodes disposed between a first side and a second side, opposite of the first side, of the semiconductor substrate. The proximal metal layer is included in an interconnect stack disposed proximate to the second side of the semiconductor substrate. The light balancing structure is disposed between the second side of the semiconductor substrate and the proximal metal layer. The light balancing structure includes a plurality of discrete segments optically aligned with a first type of pixel cells included in the plurality of pixel cells.

### TECHNICAL FIELD

This disclosure relates generally to image sensors, and in particular but not exclusively, relates to complementary metal-oxide-semiconductor image sensors.

### BACKGROUND INFORMATION

Image sensors are one type of semiconductor device that have become ubiquitous and are now widely used in digital cameras, cellular phones, security cameras, as well as, medical, automobile, and other applications. As image sensors are integrated into a broader range of electronic devices it is desirable to enhance their functionality, performance metrics, and the like in as many ways as possible (e.g., resolution, power consumption, dynamic range, size, etc.) through both device architecture design as well as image acquisition processing.

The typical image sensor operates in response to image light reflected from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bit lines that vary as a function of the incident image light. In other words, the amount of image charge generated is proportional to the intensity of the image light, which is readout as analog image signals from the column bit lines and converted to digital values to produce digital images (i.e., image data) representative of the external scene.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale; emphasis instead being placed upon illustrating the principles being described.

FIG. 1 illustrates a top view of a repeat unit for a conventional image sensor.

FIG. 2A illustrates a top view of a two-by-two pixel cell array for an image sensor including a light balancing structure, in accordance with an embodiment of the present disclosure.

FIG. 2B illustrates a cross-sectional view of an image sensor including the light balancing structure, in accordance with an embodiment of the present disclosure.

FIG. 2C illustrates a magnified portion of the cross-sectional view illustrated in FIG. 2B, in accordance with an embodiment of the present disclosure.

FIG. 2D illustrates an expanded top view of the image sensor including the light balancing structure, in accordance with an embodiment of the present disclosure.

FIG. 3A illustrates a top view of an image sensor including a light balancing structure, in accordance with an embodiment of the present disclosure.

FIG. 3B illustrates a top view of the image sensor including the light balancing structure of FIG. 3A and further including one or more dummy segments, in accordance with an embodiment of the present disclosure.

FIG. 4 illustrates an example method for fabricating a light balancing structure included in an image sensor, in accordance with an embodiment of the present disclosure.

FIG. 5 is a functional block diagram of an imaging system including an image sensor with a light balancing structure described in exemplary embodiments of FIGS. 2A-4, in accordance with embodiments of the present disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures can be exaggerated relative to other elements to help to improve understanding of various embodiments of the present invention. In addition, common but well-understood elements that are useful or necessary in a commercially feasible embodiment are often not depicted in order to facilitate a less obstructed view of these various embodiments of the present invention.

### DETAILED DESCRIPTION

Embodiments of an apparatus, system, and/or method related to an image sensor with a light balancing structure are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

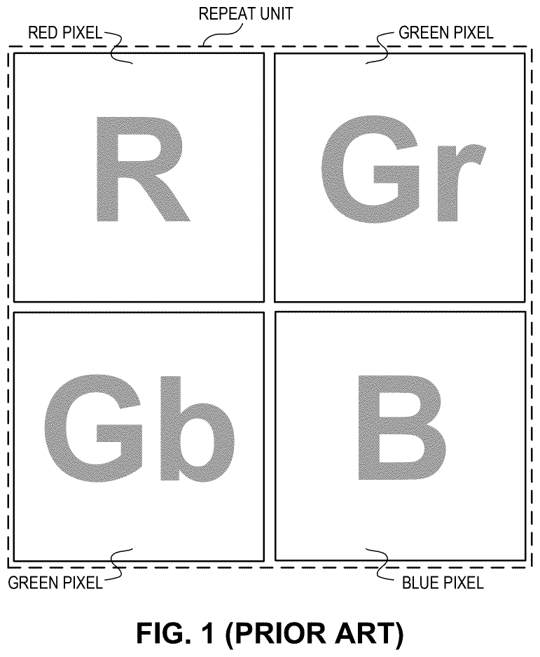

FIG. 1 illustrates a top view of a repeat unit for a conventional image sensor, which includes one red pixel (R pixel), two green pixels (e.g., a Gr pixel and a Gb pixel), and one blue pixel (B pixel) that collectively form a full color image pixel of the conventional image sensor. During operation, each of the pixels included in the repeat unit may photogenerate image charge in response to incident light that can be read out (e.g., as a voltage signal) for generating an image of an external scene. However, it has been found that optical crosstalk may asymmetrically affect the readout of the two adjacent green pixels such that there is a non-insignificant discrepancy between the signal associated with the Gr pixel and the signal associated with the Gb pixel (e.g., a GrGb difference). It has further been found that the GrGb difference varies based on the relative position of a given pixel within an array of pixels that form the conventional image sensor. More specifically, it was found that the o chief ray angle (CRA) of a given pixel, which also varies based on the relative position of the given pixel within the array of pixels, can be correlated to the GrGb difference. For example, the amount of light incident upon adjacent Gr and Gb pixels positioned proximate to an edge of the array of pixels (e.g., where the CRA is highest) may cause the corresponding signals readout from the adjacent Gr and Gb pixels to deviate by 25% or more (e.g., a GrGb difference of 25% or more), which negatively affects performance of the conventional image sensor.

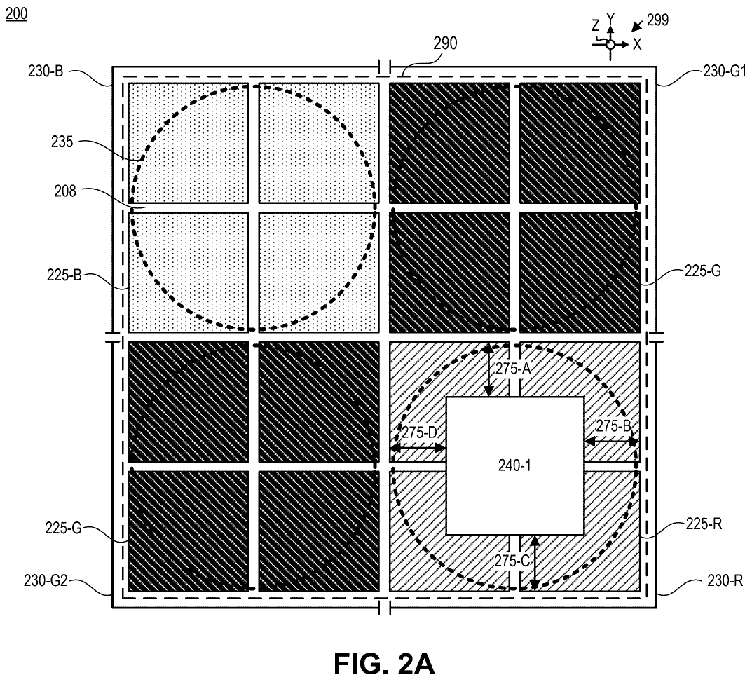

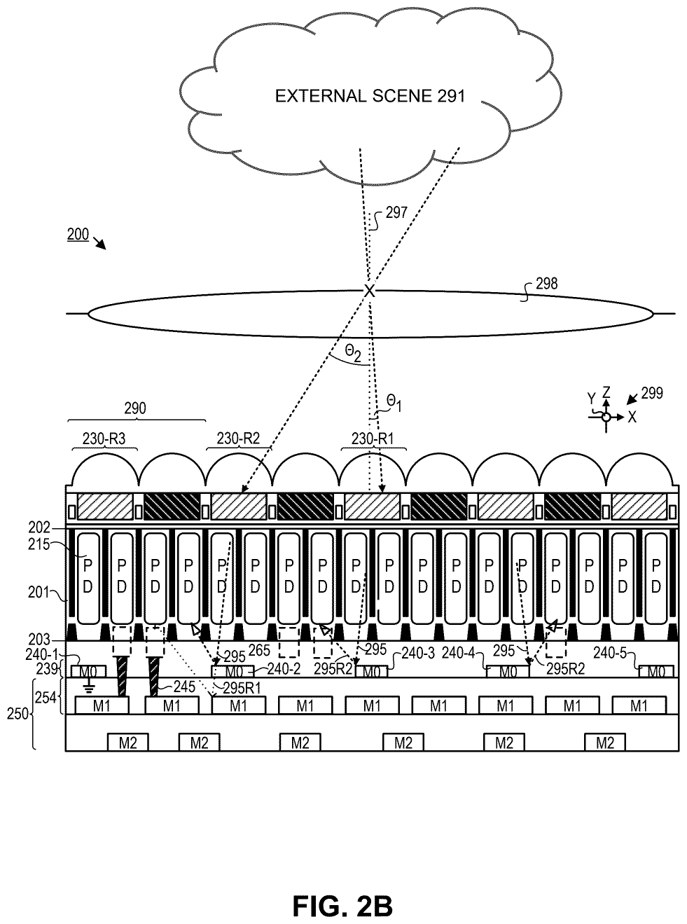

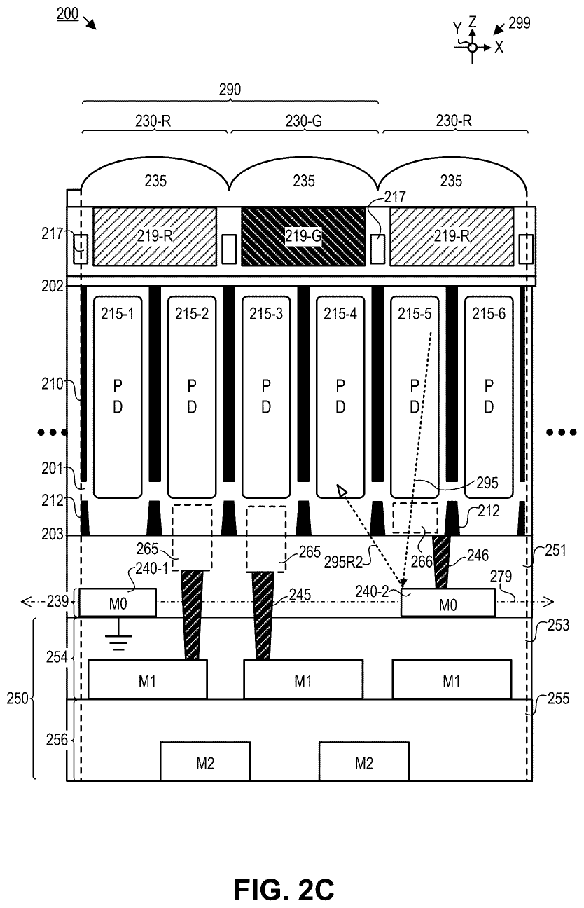

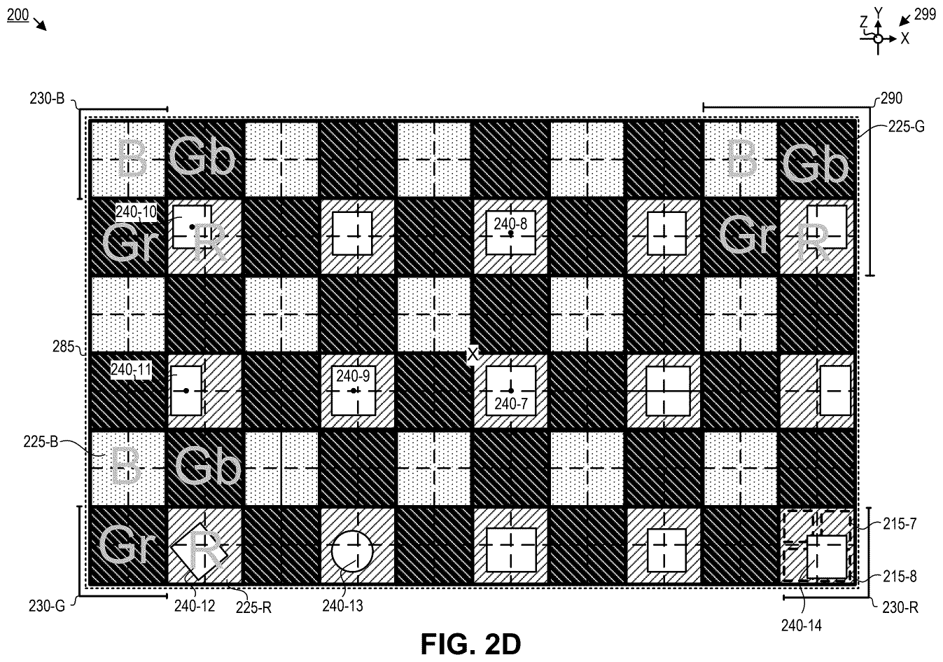

Moreover, it is appreciated that certain embodiments of the present disclosure (e.g., embodiments of image sensors that utilize architecture as illustrated, for example, in FIGS. 2A-2D) are particularly sensitive to crosstalk asymmetrically affecting adjacent green pixels since the adjacent green pixels may be utilized as image or phase detection pixels that compare the Gr and/or Gb imaging signals for various functions (e.g., phase or distance detection for accurate autofocus). Accordingly, there is a need to address asymmetric optical crosstalk that may affect image sensors.

One way to address the asymmetric optical crosstalk of conventional image sensors is to determine the readout differences between each Gr/Gb pixel pair and develop a compensation lookup table that is stored on, for example, one-time programmable memory. In other words, additional circuit elements may be included in the conventional image sensor that can be configured to compensate for the asymmetric optical crosstalk. However, due to the limitations of on-chip memory, this compensation is implemented by dividing the whole pixel array into a limited number of regions of interests (ROI) for optical compensation, with individual pixels within a given one of the ROI sharing a common compensation factor. However, the compensation lookup table does not address the underlying cause of the asymmetric optical crosstalk nor does it compensate for the asymmetric optical crosstalk that exists within the limited number of ROIs. For example, a given one of the ROIs includes multiple full color pixels that each include adjacent Gr and Gb pixels that individually encounter different degrees of asymmetric optical crosstalk meaning the GrGb difference cannot be averaged out. Additional variances such as die to die variance on a given wafer of image sensor dies, batch to batch variance, device variance associated with processing variance, and the like further complicate addressing asymmetric optical crosstalk. Moreover, even making minor changes to a known pixel layout (e.g., changes made to a color filter layer or other elements of the optical stack) would require re-measurement to determine the readout differences for the Gr/Gb pixel pairs for generating adjusted values of the compensation table.

While the compensation lookup table approach is inefficient, it may be used in conjunction with embodiments of the disclosure, which aim to address the issue of asymmetric optical crosstalk more directly by targeting at least one of the main contributors to asymmetric optical crosstalk. Specifically, it was found that longer wavelength light (e.g., red light propagating through red pixels is longer in wavelength relative to green light propagating through green pixels and blue light propagating through blue pixels) is one of the main contributors to the asymmetric optical crosstalk of adjacent green pixels. It has been determined that the red light may penetrate deeper into the substrate (e.g., relative to green light or blue light) to such an extent that the red light may reflect off underlying elements of the image sensor and subsequently be redirected, asymmetrically, to nearby photodiodes of adjacent pixels (e.g., photodiodes associated with green pixels adjacent to a given red pixel). For example, it was found that the red light may reflect off a first metal or “metal 1” layer and be redirected as optical crosstalk towards photodiodes associated with non-red pixels (e.g., green pixels) along certain directions, which may affect the sensitivity of neighboring green pixels. The first metal or “metal 1” layer may be a metal layer disposed in relative close proximity to a semiconductor substrate that the photodiodes are formed therein.

Furthermore, it was found that the asymmetric optical crosstalk of adjacent green pixels is not consistent across the pixel array. In other words, adjacent green pixels may experience different levels of optical crosstalk associated with an adjacent red pixel based on their relative position on the image sensor die. Specifically, a correlation between chief ray angle of incident light and the asymmetric optical crosstalk of adjacent green pixels was found, which will be discussed in greater detail later within this disclosure. Other factors found to be influencing the asymmetric optical crosstalk include underlying isolation structures, especially when the underlying isolation structure provides a region for pixel control circuitry that is positioned in a non-uniform manner with respect to adjacent green pixels, and reflection variance across the image sensor die.

Accordingly, embodiments of the disclosure aim to address, inter alia, asymmetric optical crosstalk by utilizing a light balancing structure disposed between the “metal 1” layer and the plurality of photodiodes of a given image sensor. In embodiments of the disclosure, the light balancing structure may be configured to reduce or eliminate asymmetric optical crosstalk by reflecting long wavelength light (e.g., red light) in a manner that reduces and/or balances the amount of crosstalk incident upon photodiodes associated shorter wavelength light (e.g., adjacent green pixels or pixel cells of a given repeat unit). In other words, embodiments of the light balancing structure disclosed herein may address one or more of the aforementioned contributors to asymmetrical optical crosstalk by redirecting light in a manner that balances optical crosstalk to two or more pixels or pixel cells (e.g., adjacent green pixels and/or adjacent pixel cells of a given repeat unit).

Additionally, by being disposed between the “metal 1” layer and a first type of pixels or pixel cells (e.g., red pixels or pixel cells), the light balancing structure further inhibits the “metal 1” layer from reflecting the longer wavelength light and resulting in asymmetric optical crosstalk. Embodiments of the light balancing structure disclosed herein are defined by a plurality of discrete segments. In some embodiments, the plurality of discrete segments may be further arranged to address other contributors to asymmetric optical crosstalk (e.g., chief ray angle, isolation structure position and/or pixel control circuitry position, reflection variance across image sensor die, processing variance across image sensor die and/or wafer, and the like). In other words, while the plurality of discrete segments that define the light balancing structure may be configured to redirect most of the longer wavelength light (e.g., red light) back to the photodiodes associated with the longer wavelength light (e.g., red pixels or red pixel cells) to reduce overall optical crosstalk, in some embodiments the plurality of discrete segments may further be configured to counter or otherwise mitigate the other contributors to asymmetric optical crosstalk and/or otherwise balance crosstalk between green pixels adjacent to red pixels to reduce non-uniformity in light sensitivity. For example, a portion of the red light may be intentionally redirected by the light balancing structure towards one or more of the adjacent green pixels or pixel cells in a given repeat unit such that the adjacent green pixels or pixel cells have similar amounts of crosstalk. The degree of redirection (or lack thereof) provided by the light balancing structure may subsequently be adjusted (e.g., by adjusting one or more of relative position with respect to a center of the pixel or pixel cell, size, shape, orientation, or the like of individual segments included in the plurality of discrete segments that define the light balancing structure) across the image sensor die to compensate for the variance in asymmetric optical crosstalk that changes based on the respective position of a given pixel or pixel cell in a pixel array.

FIGS. 2A-2D illustrate various views of an image sensor 200 including a light balancing structure 239, in accordance with embodiments of the present disclosure. The image sensor 200 includes an objective 298 (e.g., one or more optical elements) to focus or otherwise redirect light to be incident upon an image sensor array formed by multiple instances of a two-by-two pixel cell array 290. Each instance of the two-by-two pixel cell array 290 includes a plurality of pixel cells 230 (e.g., red pixel cells 230-R including 230-R1, 230-R2, and 230-R3, green pixel cells 230-G including 230-G1 and 230-G2, and blue pixel cells 230-B) formed in or on a semiconductor substrate 201. The semiconductor substrate 201 has a first side 202 and a second side 203 opposite the first side 202. Each pixel cell included in the plurality of pixel cells 230 is defined, at least in part, by liked-colored pixels included in a plurality of pixels 225 (e.g., red pixels 225-R, green pixels 225-G, or blue pixels 225-B). Individual pixels included in the plurality of pixels 225 are separated from one another by an isolation structure 208 (e.g., one or more dielectric or oxide materials such as silicon dioxide), which may include a deep trench isolation structure 210 and/or a shallow trench isolation structure 212. The individual pixels included in the plurality of pixels 225 further include a corresponding photodiode (e.g., first photodiode 215-1, a second photodiode 215-2, a third photodiode 215-3, a fourth photodiode 215-4, a fifth photodiode 215-5, a sixth photodiode 215-6, a seventh photodiode 215-7, an eight photodiode 215-8, and so on) included in a plurality of photodiodes 215 (e.g., pinned photodiodes having doped regions with an opposite charge carrier type relative to the majority charge carrier type of the semiconductor substrate 201 such that an outer perimeter of the doped region forms a PN junction or a PIN junction of a photodiode). Each pixel cell included in the plurality of pixel cells 230 further includes at least one color filter (e.g., a red color filter 219-R, a green color filter 219-G, or a blue color filter 219-B) included in a plurality of color filters 219. Color filters included in the plurality of color filters 219 are separated from one another, at least in part, by a metal grid structure 217 (e.g., aluminum, copper, tungsten, or other metals arranged in a grid to laterally surround and plurality of color filters 219). Each pixel cell included in the plurality of pixel cells 230 further includes one or more microlenses included in a plurality of microlenses 235 (e.g., molded plastic or polymer material to form an optical structure to focus or otherwise direct incident light onto the plurality of photodiodes 215).

In the illustrated embodiments of FIGS. 2A-2D, the semiconductor substrate 201 may correspond to a part of or an entirety of a semiconductor wafer (e.g., a silicon wafer). In some embodiments, the semiconductor substrate 201 includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, the semiconductor substrate 201 may correspond to any semiconductor material or combination of materials that may be doped or otherwise configured to include the plurality of photodiodes 215 included in the image sensor array of the image sensor 200. For example, in some embodiments, the semiconductor substrate 201 may correspond to one or more epitaxial layers (e.g., P or N doped silicon) formed on a carrier wafer. In such an embodiment, the plurality of photodiodes 215 may be formed in the one or more epitaxial layers corresponding to the semiconductor substrate 201 while the carrier wafer may be removed or otherwise thinned during fabrication. In one embodiment, the semiconductor substrate 201 is formed of intrinsic or extrinsic silicon material having regions doped sufficiently to form the plurality of photodiodes 215.

The image sensor 200 further includes pixel transistors 265 (e.g., pixel control circuitry such as transfer transistors including a floating diffusion region, reset transistors, row select transistors, source-follower transistors, other transistors, other circuitry elements such as memory elements, or combinations thereof) disposed proximate to the second side 203 of the semiconductor substrate 201. The pixel transistors 265 may include source/drain regions (e.g., doped regions of the semiconductor substrate 201), gate electrodes (e.g., polycrystalline silicon), gate dielectrics (e.g., silicon dioxide, hafnium dioxide, other insulating materials, or combinations thereof).

As illustrated in FIGS. 2A-2D, the image sensor 200 further includes an interconnect stack 250 disposed proximate to the second side 203 of the semiconductor substrate 201. The interconnect stack includes a proximal metal layer 254 (e.g., a “metal 1” layer) and one or more non-proximal metal layers (e.g., non-proximal metal layer 254, which corresponds to a “metal 2” layer and/or additional non-proximal metal layers not illustrated such as a “metal 3” layer, a “metal 4” layer and so on). The proximal metal layer 254 includes metal contacts, M1, while the non-proximal metal layer 256 includes metal contacts M2. It is noted that the proximal metal layer 254 may include vias 245 (e.g., one or more vertical interconnects that are conductive) that couple the metal contacts, M1, of the proximal metal layer 254 to the pixel transistors 265. The metal contacts M1 and M2 (e.g., Al, Au, Cu, W, Ti, other metals, metal alloys, polycrystalline silicon, other conductive materials, or combinations thereof) are respectively disposed within inter-metal dielectric 253 (e.g., inorganic oxides such as silicon dioxide, nitrides such as silicon nitride, spin-on glass, or other materials such as organic polymers) and inter-metal dielectric 255 (e.g., inorganic oxides such as silicon dioxide, nitrides such as silicon nitride, spin-on glass, or other materials such as organic polymers). The image sensor 200 further includes the light balancing structure 239 disposed within inter-layer dielectric 251 between the second side 203 of the semiconductor substrate 201 and the interconnect stack 250. The light balancing structure 239 includes a plurality of discrete segments 240 (e.g., 240-1, 240-2, 240-3, 240-4, 240-5, 240-6, 270-7, 240-8, 240-9, 240-10, 240-11, 240-12, 240-13, 240-14, and so on, which in some views are annotated as “M0” in FIGS. 2B-2C) to mitigate asymmetric optical crosstalk. It is appreciated that the light balancing structure 239 may have a common composition as the metal contacts of the proximal metal layer 254 and/or the non-proximal metal layer 256 (e.g., a titanium liner filled with tungsten).

It is appreciated that the views presented in FIGS. 2A-2D may omit certain features of the image sensor 200 to avoid obscuring details of the disclosure. In other words, not all elements of the image sensor 200 may be labeled, illustrated, or otherwise shown within FIGS. 2A-2D or other figures throughout the disclosure. It is further appreciated that in some embodiments, the image sensor 200 may not necessarily include all elements shown.

FIG. 2A illustrates a top view (e.g., along an x-y plane in accordance with coordinate system 299) of an instance of the two-by-two pixel cell array 290 for the image sensor 200 including the light balancing structure 239, in accordance with an embodiment of the present disclosure. The two-by-two pixel cell array 290 includes the isolation structure 208, the plurality of pixels 225 (e.g., the blue pixels 225-B, the green pixels 225-G, and the red pixels 225-R), the plurality of pixel cells 230 (e.g., the blue pixel cells 230-B, the green pixel cells 230-G including 230-G1 and 230-G2, and the red pixel cells 230-R), the plurality of microlenses 235, and the light balancing structure 239 (e.g., formed by the plurality of discrete segments including discrete segment 240-1). It is appreciated that in some embodiments, the two-by-two pixel cell array 290 may correspond to a minimum repeat unit and/or a full color image pixel of the image sensor 200.

The plurality of pixel cells 230 are arranged in rows and columns to form the two-by-two pixel cell array 290. The two-by-two pixel cell array 290 includes one red pixel cell, 230-R, one blue pixel cell, 230-B, and two green pixel cells, 230-G1 and 230-G2. As illustrated, the plurality of pixels 225 collectively form the plurality of pixel cells 230 with individual pixels included in the plurality of pixels 225 separated from one another, at least in part, by the isolation structure 208 (see, e.g., the shallow trench isolation structure 212 and/or the deep trench isolation structure 210 illustrated in FIG. 2C, which may individually or collectively correspond to the isolation structure 208). Each pixel cell included in the plurality of pixel cells 230 includes a two-by-two array of same-colored pixels included in the plurality of pixels 225. For example, the blue pixel cell 230-B is formed by a two-by-two array of the blue pixels 225-B, the red pixel cell 230-R is formed by a two-by-two array of the red pixels 225-R, and the green pixel cells 230-G1 and 230-G2 are each formed by a two-by-two array of the green pixels 225-G. Since each pixel cell included in the plurality of pixel cells 230 in the example includes exactly four pixels included in the plurality of pixel 225, the plurality of pixel cells 230 may be generally referred to as “4C” pixel cells. However, it is appreciated that in other embodiments, the plurality of pixel cells 230 may include more or less pixels per pixel cell (e.g., each pixel cell included in the plurality of pixel cells 230 may include 1 pixel, 2 pixels, 8 pixels, 16 pixels, or any other amount of pixels included in the plurality of pixels 225 per pixel cell). In the illustrated embodiment, each pixel cell included in the plurality of pixel cells 230 includes a microlens included in the plurality of microlenses 235 (e.g., a one-to-one ratio between pixel cells included in the plurality of pixel cells 230 and microlenses included in the plurality of microlenses 235). However, in other embodiments, a different arrangement of microlenses may be utilized (e.g., a one-to-one ratio, a two-to-one ratio, or other ratio between pixels included in the plurality of pixels 225 and microlenses included in the plurality of microlenses 235).

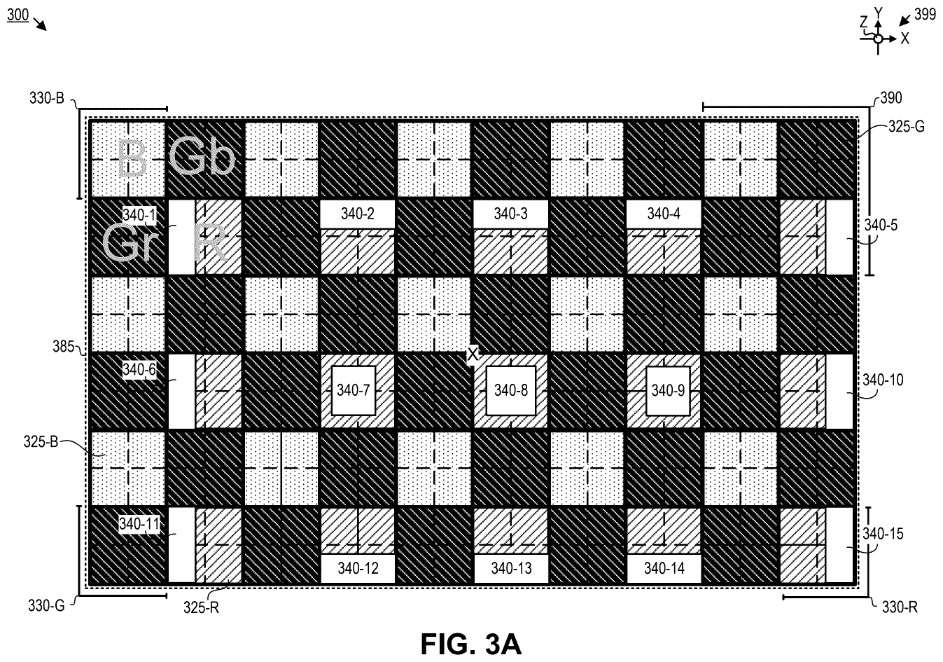

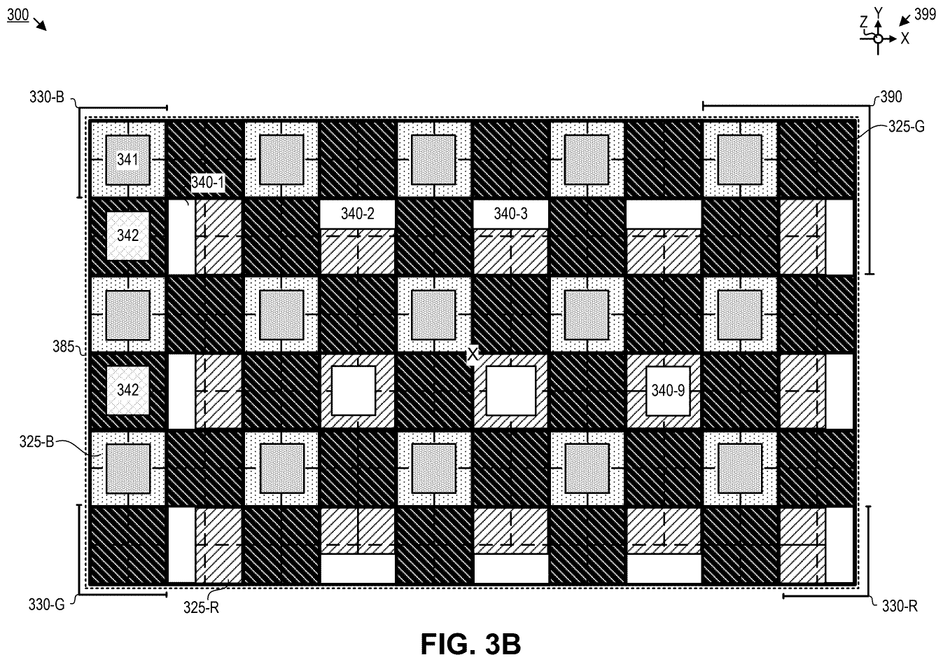

As illustrated in FIG. 2A, the two-by-two pixel cell array 290 includes the blue pixel cell 230-B, the red pixel cell 230-R, and the two green pixel cells 230-G1 and 230-G2. As previously discussed, longer wavelength light (e.g., red light) that propagates through a first type of pixel cells (e.g., the red pixel cells 230-R) included in the plurality of pixel cells 230 may be reflected or otherwise contribute to asymmetric optical crosstalk incident upon a second type of pixel cells (e.g., the green pixel cells 230-G1 and 230-G2) included in the plurality of pixel cells 230. The light balancing structure 239 is subsequently positioned to be optically aligned (e.g., in optical communication) with the first type of pixel cells to redirect the longer wavelength light back to the first type of pixel cells and/or to a neighboring or adjacent one of the second type of pixel cells. For example, discrete segment 240-1 is positioned to redirect at least some of the red light propagating through the red pixel cell 230-R back to the red pixel cell 230-R to reduce total optical crosstalk and may also further redirect some of the red light propagating through the red pixel cell 230-R to one or both of the green pixel cells 230-G1 and 230-G2 to further reduce asymmetric optical crosstalk between the green pixel cells 230-G1 and 230-G2. It is appreciated that depending on the position of the discrete segment 240-1, the amount of red light redirected to green pixel cells 230-G1 and 230-G2 (e.g., the second type of pixel cells adjacent to one of the first type of pixel cells) may be varied to mitigate asymmetric optical crosstalk (e.g., green pixel cell 230-G2 may receive more redirected red light relative to the green pixel cell 230-G1, or vice versa, to balance the amount of optical crosstalk that the two adjacent green pixel cells 230-1 and 230-2 receive). In the illustrated embodiment, the discrete segment 240-1 included in the light balancing structure 239 does not completely cover the red pixel cell 230-R. For example, while the discrete segment 240-1 extends over each pixel included in red pixel cell 230-R (e.g., the discrete segment 240-1 extends over at least four pixels included in the red pixel cell 230-R), there is a lateral separation distance 275 (e.g., 275-A, 275-B, 275-C, and 275-D) between a perimeter boundary of the discrete segment 240-1 and a corresponding perimeter boundary of the red pixel cell 230-R. The discrete segment 240-1 may further be configured based on relative location within a pixel array on a die of the image sensor 200. For example, distance from a perimeter boundary of the pixel cell along vertical or horizontal direction (e.g., array edge) may be utilized to configure the specific location of the discrete segment 240-1. In the same or other embodiments, the discrete segment 240-1 may be configured by adjusting the discrete segment 240-1 in size, shape, orientation, lateral area, and/or position (e.g., based on lateral separation distance 275 such as one or more of 275-A, 275-B, 275-C, and 275-D) with respect to the red pixel cell 230-R to compensate for one or more contributors to asymmetric optical crosstalk to neighboring green pixel cells 230-G1 and 230-G2 (e.g., chief ray angle, isolation structure position and/or pixel control circuitry position, reflection variance across image sensor die, processing variance across image sensor die and/or wafer, and the like) that vary with respect to position on the image sensor 200. In some embodiments, the discrete segment 240-1 may extend over more or less pixels in a given pixel cell (e.g., one pixel, two pixels, or three pixels) depending on the relative position of the red pixel cell 230-R with respect to a center of the image sensor 200 (see, e.g., FIGS. 2D, 3A, and 3B).

In the illustrated embodiment of FIG. 2A, a first lateral area of the discrete segment 240-1 included in the light balancing structure 239 is less than a second lateral area of an optically aligned microlens included in the plurality of microlenses 235. In the same or other embodiments, the first lateral area of the discrete segment 240-1 is greater than a third lateral area of a given one of the optically aligned one of the red pixels 225-R, but less than a fourth lateral area of the red pixel cell 230-R. It is appreciated that lateral areas discussed herein (e.g., the first lateral area, the second lateral area, the third lateral area, and the fourth lateral area) are with respect to the x-y plane of the coordinate system 299. It is further appreciated when viewed from a top view (e.g., as illustrated in FIG. 2A), elements are located on different z-positions of the coordinate system 299, but are otherwise optically aligned. For example, while the red pixel cell 230-R, the discrete segment 240-1, and one of the plurality of microlenses 235 are each located on different planes (e.g., different z-positions), FIG. 2A shows the aforementioned elements are optically aligned or otherwise in optical communication such that a ray of light may propagate from the one of the plurality of microlenses 235, through the red pixel cell 230-R, until reaching the discrete segment 240-1. Accordingly, it is appreciated that references to terms like “lateral area” or “separation distance” or the like are in reference to a planar projection or similar view (e.g., a planar projection onto an x-y plane based on the coordinate system 299). For example, the separation distance 275 is in reference to lateral distances on the x-y plane of the coordinate system 299 and does not correspond to the vertical separation distance (e.g., along the z-axis of the coordinate system 299, which can be seen in FIG. 2B).

In some embodiments, the illustrated view of FIG. 2A shows a multi-color image pixel of an image sensor. For example, the red pixel cell 230-R, the green pixel cells 230-G1 and 230-G2, and the blue pixel cell 230-B may collectively form an instance of a multi-color image pixel included in a pixel array of an image sensor. The multi-color image pixel includes a group of four pixel cells arranged in a two-by-two array. The group of four pixel cells includes a red pixel cell (e.g., 230-R), two green pixel cells (e.g., 230-G1 and 230-G2) adjacent to the red pixel cell, and a blue pixel cell (e.g., 230-B) adjacent to the two green pixel cells. Each pixel cell included in the group of four pixel cells includes at least four photodiodes disposed within a semiconductor substrate (see, e.g., FIG. 2B-2C). The multi-color image pixel further includes a proximal metal layer (e.g., proximal metal layer 254 as illustrated in FIGS. 2B-2C) included in an interconnect stack (e.g., interconnect stack 250) coupled to the semiconductor substrate (e.g., semiconductor substrate 201). The multi-color image pixel further includes a discrete segment (e.g., 240-1) of a light balancing structure (e.g., light balancing structure 239 illustrated in FIG. 2B-2C) optically aligned with the red pixel cell included in the group of four pixel cells. The discrete segment is further disposed between the semiconductor substrate and the proximal metal layer. In some embodiments, the discrete segment is adapted to mitigate asymmetric optical crosstalk for the two green pixel cells by positioning the discrete segment over the red pixel cell based, at least in part, on a relative location of the red pixel cell in a pixel array on the image sensor.

FIG. 2B illustrates a cross-sectional view (e.g., along the x-z plane as indicated by the coordinate system 299) of the image sensor 200 including the light balancing structure 239, in accordance with an embodiment of the present disclosure. As illustrated, the image sensor 200 is formed by multiple instances of the two-by-two pixel cell array 290 arranged in rows and columns to form the image sensor array, which is further illustrated in FIG. 2D. Referring back to FIG. 2B, the plurality of pixel cells 230 (e.g., 230-R1, 230-R2, 230-R3, and other unlabeled pixel cells) are disposed in or on the semiconductor substrate 201. Each pixel cell included in the plurality of pixel cells 230 includes one or more photodiodes included in the plurality of photodiodes 215 disposed between the first side 202 and the second side 203 of the semiconductor substrate 201. The image sensor 200 further includes the proximal metal layer 254 included in the interconnect stack 250 disposed proximate to the second side 203 of the semiconductor substrate 201.

The light balancing structure 239 is disposed between the second side 203 of the semiconductor substrate 201 and the proximal metal layer 254. As discussed previously, the light balancing structure 239 includes the plurality of discrete segments 240, including 240-1, 240-2, 240-3, 240-4, and 240-5, optically aligned with the first type of pixel cells (e.g., red pixel cells 230-R including 230-R1, 230-R2, and/or 230-R3) included in the plurality of pixel cells 230. It is appreciated that the plurality of discrete segments 240, including 240-1, 240-2, 240-3, 240-4, and 240-5, of the light balancing structure 239 are annotated as “M0” to indicate that the light balancing structure 239 may correspond to a “metal 0” layer that may be formed using the same materials and manufacturing processes as metal layers included in the interconnect stack 250 (e.g., the proximal metal layer 254 and the one or more non-proximal metal layers 256). In other words, the light balancing structure 239 is advantageously compatible with existing processes for back-end-of-line processing formation.

In the illustrated embodiment of FIG. 2B, the plurality of discrete segments 240 do not, individually, extend beyond the first type of pixel cells. For example, the plurality of discrete segments 240 are only disposed between the first type of pixel cells (e.g., the red pixel cells 230-R) and the proximal metal layer 254. It is appreciated that limiting the lateral area of the plurality of discrete segments 240 may provide the benefit of maintaining sufficient space for the formation of other device components (e.g., provide sufficient room metal contacts and/or vias of the proximal metal layer 254 to contact with the pixel transistors 265 and/or other components of the image sensor 200).

In embodiments, individual segments included in the plurality of discrete segments 240 may be configured to be electrically floating or coupled to a ground reference voltage (see, e.g., the discrete segment 240-1 illustrated in FIG. 2B). As discussed previously, the pixel transistors 265 include one or more transistors (e.g., pixel control circuitry) disposed proximate to the second side 203 of the semiconductor substrate 201. Metal contacts (e.g., metal traces wires, or segments) disposed within the proximal metal layer 254 (e.g., metal contacts annotated as “M1”) may subsequently be electrically coupled directly or indirectly to the one or more transistors included in the pixel transistors 265 (e.g., through a via 245). Thus, in some embodiments, the plurality of discrete segments 240 do not provide signal routing or otherwise directly facilitate transfer of photogenerated charge from the plurality of photodiodes 215 to the proximal metal layer 254. Rather, the plurality of discrete segments 240 reflect incident red light that has propagated through the red pixel cells included in the plurality of pixel cells 230 to mitigate asymmetric optical crosstalk. It is appreciated that having the plurality of discrete segments 240 of the light balancing structure grounding or floating may provide the benefit of mitigating the plurality of discrete segments 240 from influencing readout of the plurality of pixel cells 230.

As illustrated in FIG. 2B, the image sensor 200 is configured to generate an image of an external scene 291 via the objective 298. However, as discussed previously, asymmetric optical crosstalk may have a detrimental effect on the performance of the image sensor 200 (e.g., quality of the image generated, autofocus, and the like). Specifically, light 295 may reflect off the proximal metal layer 254 in a manner that results in the asymmetric crosstalk, for example, as illustrated by reflected light ray 295R1. To mitigate the crosstalk difference to neighboring green pixel cells (e.g., diagonally adjacent Gr and Gb green pixel cells) due to incident light angle, the image sensor 200 includes the light balancing structure 239, which includes the plurality of discrete segments 240 optically aligned with each respective first type of pixel cells 230 (e.g., red pixel cells 230-R such as 230-R1, 230-R2, 230-R3, and so on) and positioned to direct the light 295 to neighboring green pixel cells, for example, as illustrated by reflected light ray 295R2, with light variation according to separation distance 275 (e.g., 275-A, 275-B, 275-C, and 275-D illustrated in FIG. 2A) with respect to the red pixel cell 230-R so as to minimize differences between neighboring green pixel cells (e.g., a GrGb difference).

However, it has been found that the degree of asymmetric optical crosstalk varies based on relative position of a given pixel or pixel cell included in the plurality of pixel cells 230 on the die of the image sensor 200 and thus performance of the light balancing structure 239 may be improved by adjusting the position of the plurality of discrete segments 240 (e.g., 240-1, 240-2, 240-3, 240-4, 240-5) based on their relative position within the pixel array of the image sensor 200. It was found that one way to relate the variance of the asymmetric optical crosstalk is based on the chief ray angle of light, which corresponds to the angle at which light is incident upon the image sensor 200. Specifically, reference is being made to the angle at which light that passes through a center of the objective 298 is incident upon a given pixel or pixel cell included in the plurality of pixel cells 230. Axis 297 shows a normal to the image sensor 200 with respect to any planar surface of the image sensor 200 (e.g., the first side 202, the second side 203, or any other surface of the image sensor 200 that is parallel to the x-y plane of the coordinate system 299). In the illustrated embodiment, the axis 297 intersects a center, “X,” of the objective 298, which is centrally aligned with the image sensor array of the image sensor 200 formed by multiple instances of the two-by-two pixel cell array 290. It is appreciated that the axis 297 is indicative of where the chief ray angle with respect to imaging plane of the image sensor 200 is lowest. However, as light is incident upon the image sensor 200 away from the lateral center, the chief ray angle increases proportionally. Thus, the chief ray angle for a given pixel or pixel cell included in the plurality of pixel cells 230 increases as the position of the given pixel or pixel cells moves towards a perimeter of the image sensor 200. Accordingly, the chief ray angle, θ₁, associated with the location of the red pixel cell 230-R1 is less than the chief ray angle, θ₂, associated with the location of the red pixel cell 230-R2. Similarly, the chief ray angle associated with the location of the red pixel cell 230-R3 is greater than the chief ray angles associated with the location of the red pixel cells 230-R1 and 230-R2. In other words, the first type of pixel cells (e.g., the red pixel cells 230-R) have associated chief ray angles based on a relative pixel location within the image sensor 200, which in turn influences the asymmetrical optical crosstalk. Consequently, in some embodiments, individual segments included in the plurality of discrete segments 240 of the light balancing structure 239 are arranged based on the associated chief ray angles. For example, the size, shape, orientation, lateral area, relative position (e.g., with respect to a center of a given pixel or pixel cell), or the like of the individual segments included in the plurality of discrete segments 240 may be adjusted based on the associated chief ray angles.

FIG. 2C illustrates a magnified portion of the cross-sectional view of the image sensor 200 illustrated in FIG. 2B, in accordance with an embodiment of the present disclosure. As illustrated, the two-by-two pixel cell array 290 includes at least a first type of pixel cell (e.g., red pixel cell 230-R) and a second type of pixel cell (e.g., green pixel cell 230-G). Each pixel cell included in the plurality of pixel cells further includes optically aligned photodiodes included in the plurality of photodiodes 215, optically aligned color filters included in the plurality of color filters 219, and an optically aligned microlens included in the plurality of microlenses 235. For example, two photodiodes (e.g., 215-1 and 215-2) included in the red pixel cell 230-R are optically aligned with one of the plurality of microlenses 235 (i.e., leftmost microlens included in the plurality of microlenses 235 in the illustrated view) and one of the plurality of color filters included in the plurality of color filters 219 (i.e., red color filter 219-R that is to the left of green color filter 219-G).

The image sensor 200 further includes the light balancing structure 239 disposed between the plurality of photodiodes 215 and the proximal metal layer 254 of the interconnect stack 250. It is further appreciated that in some embodiments, individual segments included in the plurality of segments M0 of the light balancing structure 239 are confined to a lateral area defined by the first type of pixel cells (e.g., the red pixel cells 230-R) included in the plurality of pixel cells 230. For example, the discrete segments 240-1 and 240-2 do not extend beyond a pixel region associated the red pixel cells 230-R that is defined by the isolation structure 208. In other words, in some embodiments, the individual segments included in the plurality of discrete segments 240 of the light balancing structure 239 are not in optical communication with non-red pixel cells included in the plurality of pixel cells 230. In some embodiments, individual segments included in the plurality of discrete segments 240 are electrically floating or coupled to ground. For example, discrete segment 240-1 is directly or indirectly coupled to a ground or reference voltage (e.g., through one or more metal contacts and/or vias included in the interconnect stack 250). In another example, the discrete segment 240-2 is coupled by via 246 to a component of the image sensor 200 disposed in or on semiconductor substrate 201 that is coupled to a ground or reference voltage. For example, a well 266 or other component of the image sensor 200 (e.g., a conductive filling of the shallow trench isolation structure 212) that has been grounded or otherwise coupled to a reference voltage may be coupled to the discrete segment 240-2. In contrast, one or more transistors included in pixel transistors 265 may be coupled to metal contacts (e.g., metal traces wires, or segments labeled as “M1”) included in the proximal metal layer 254 by vias 245. In some embodiments, the vias 245 and one or more individual segments included in the plurality of discrete segments 240 of the light balancing structure 239 are disposed in a same dielectric layer (e.g., the inter-layer dielectric 251), which may reduce fabrication complexity, cost, and time. Accordingly, in some embodiments, at least one of the vias 245 and at least a portion of the plurality of discrete segments 240 included in the light balancing structure 239 may extend through a common plane 279. In some embodiments, the common plane 279 is parallel with the first side 202 and/or the second side 203 of the semiconductor substrate 201. As previously discussed, in some embodiments the proximal metal layer 254 and the plurality of discrete segments 240 of the light balancing structure 239 may include a same metal material to facilitate processing compatibility and simplification.

FIG. 2D illustrates an expanded top view of the image sensor 200 including the light balancing structure 239 illustrated in FIGS. 2A-2D, in accordance with an embodiment of the present disclosure. The illustrated view shows the multiple instances of the two-by-two pixel cell array 290, which includes one pixel cell included in the first type of pixel cells (e.g., red pixel cells 230-R annotated by “R”), two pixel cells included in the second type of pixel cells (e.g., green pixel cells 230-G annotated by “Gr and “Gb”), and one pixel cell included in the third type of pixel cells (e.g., blue pixel cells 230-B annotated by “B”), arranged in rows and columns to form the image sensor array of the image sensor 200. In the illustrated view, the plurality of pixel cells 230 are 4C pixel cells, which includes exactly four pixels per pixel cell as indicated by the dashed lines. For example, each blue pixel cell 230-B includes four blue pixels 225-B. Similarly, each red pixel cell 230-R includes four red pixels 225-R and each green pixel cell 230-G includes four green pixels 225-G. Furthermore, it is appreciated that each pixel included in the plurality of pixels 225 includes at least one photodiode included in the plurality of photodiodes 215 (e.g., the labeled red pixel cell 230-R includes four photodiodes including photodiodes 215-7 and 215-8; one photodiode for each pixel included in the red pixel cell 230-R).

In the illustrated embodiment, the plurality of discrete segments (e.g., 240-7 through 240-14) are arranged or otherwise configured to mitigate asymmetric optical crosstalk, in accordance with embodiments of the present disclosure. One way the plurality of discrete segments 240 is configured to mitigate asymmetric optical crosstalk is by having each individual segment included in the plurality of discrete segments 240 of the light balancing structure 239 optically aligned with a corresponding one of the first type of pixel cells (e.g., the red pixel cells 230-R) such that the individual segments redirect light back to the one or more photodiodes associated with the corresponding one of the first type of pixel cells. Another way the plurality of discrete segments 240 is configured to mitigate asymmetric optical crosstalk is by arranging or otherwise configuring the individual segments based on the associated chief ray angles associated with the corresponding one of the first type of pixel cells. For example, in the illustrated view, “X” indicates a lateral center of the image sensor 200, where the chief ray angle for the corresponding one of the first type of pixel cells included in the plurality of pixel cells 230 is zero. The chief ray angle for the corresponding one of the first type of pixel cells included in the plurality of pixel cells 230 increases the farther the corresponding one of the first type of pixel cells is from the lateral center of the image sensor 200. As discussed previously, it was found that the asymmetric optical crosstalk variance is based on, at least in part, or otherwise associated with the chief ray angle. Thus, configuring the individual segments based on the associated chief ray angles of the corresponding one of the first type of pixel cells may further mitigate asymmetric optical crosstalk.

Accordingly, it is appreciated that the plurality of discrete segments 240 of the light balancing structure 239 may be configured to have one or more features shifted proportionally to the chief ray angle of a given optically aligned pixel or pixel cell. The one or more features of the plurality of discrete segments 240 may include size of individual segments, shape of individual segments, orientation of individual segments, lateral area of individual segments, position of individual segments with respect to a center of the corresponding one (e.g., optically aligned) of the first type of pixel cells, and combinations thereof. Accordingly, in some embodiments, adjacent segments included in the plurality of discrete segments 240 may have at least one of different sizes, different shapes, different orientations, different lateral areas, different positions with respect to a center of the first type of pixel cells, or combinations thereof. In one example, discrete segment 240-11 is adjacent to discrete segment 240-12, which have different orientations (e.g., the discrete segment 240-12 is rotated approximately 45° counterclockwise relative to the discrete segment 240-11). In another example, the discrete segments 240-12 and 240-13 have different shapes (e.g., a rectangular shape and a circle shape, respectively). In another example, the discrete segment 240-11 has a different shape, size, and/or lateral area relative to the discrete segment 240-10, which is adjacent to the discrete segment 240-11. In another example, the discrete segment 240-11 and the discrete segment 240-10 have different positions with respect to an optically aligned first type of the pixel cell included in the plurality of pixel cells 230. For example, the center, marked by a black circle, of the discrete segment 240-11 is positioned at a midpoint between two pixels included in a corresponding optically aligned pixel cell. In contrast, the center, also marked by a black circle, of the discrete segment 240-10 is not positioned at a midpoint between two pixels included in a corresponding optically aligned pixel cell or aligned with an optical center of the pixel cell.

In some embodiments, center-to-center distances between the individual segments included in the plurality of discrete segments 240 of the light balancing structure 239 and respective optically aligned pixel cells included in the first type of pixel cells (e.g., red pixel cells 230-R) are arranged such that the center-to-center distances increase radially towards a perimeter of the image sensor 200. For example, in the illustrated embodiment, discrete segment 240-7 is closest to the center, marked by an “X” of the image sensor 200 and thus has a lower chief ray angle relative to the chief ray angle of other discrete segments (e.g., 240-8, 240-9, 240-10, 240-11, and so on) included in the plurality of discrete segments 240. Accordingly, a center of the discrete segment 240-7, marked by a black circle, is approximately centered over the optically aligned pixel cell included in the first type of pixel cells (e.g., the center of the optically aligned pixel cell indicated by the dashed lines that divide the optically aligned pixel cell into a two-by-two array of pixels intersects with the center of the discrete segment 240-7). In other words, there is a zero or near-zero center-to-center distance between the center of the discrete segment 240-7 and the center of the optically aligned pixel cell. In contrast, other ones of the first type of pixel cells included in the plurality of pixel cells 230 have a greater center-to-center distance that increases radially towards a perimeter boundary 285 of the image sensor 200. For example, the center-to-center distance of discrete segment 240-9 and the optically aligned pixel cell increases (e.g., the center of the discrete segment 240-9 is shifted to the left to the center of a corresponding optically aligned pixel cell). In a further example, the center-distance distance between the discrete segment 240-11 and the pixel cell optically aligned with the discrete segment 240-11 is greater than the center-to-center distance between the discrete segment 240-9 and the pixel cell optically aligned with the discrete segment 240-9 because the pixel cell optically aligned with the discrete segment 240-11 has a greater chief ray angle than the chief ray angle of the pixel cell optically aligned with the discrete segment 240-9. More generally, in some embodiments the center-to-center distances between the individual segments included in the plurality of discrete segments 240 and respective optically aligned pixel cells included in the first type of pixel cells are based on the associated chief ray angles.

In another example, the discrete segment 240-7 of the light balancing structure 239 may be referred to as a first segment optically aligned with a first pixel cell included in the first type of pixel cells and any other discrete segment included in the light balancing structure 239 (e.g., discrete segment 240-8, 240-9, 240-10, 240-11, 240-12, 240-13, 240-14, and/or other unlabeled discrete segments) may be referred to as a second segment optically aligned with a second pixel cell included in the first type of pixel cells. In some embodiments, the first segment is optically centered with respect to the first pixel cell and the second segment is optically off-center with respect to the second pixel. In the same embodiment, a first chief ray angle of the first pixel cell is less than a second chief ray angle of the second pixel cell. In the same or other embodiments, the first segment is disposed between four photodiodes included in the first pixel cell and the proximal metal layer (see, e.g., based on FIGS. 2B and 2C when viewed in the context of FIG. 2D where the proximal metal layer corresponds to proximal metal layer 254 illustrated in FIGS. 2B and 2D). In the same or other embodiments, the second segment is disposed between two or less photodiodes included in the second pixel cell and the proximal metal layer (e.g., when the second segment corresponds to discrete segment 240-11, for example, and the proximal metal layer corresponds to proximal metal layer 254 illustrated in FIGS. 2B and 2D). It is appreciated that in the illustrated embodiment, each pixel cell included in the plurality of pixel cells 230 includes a two-by-two array of four photodiodes (see, e.g., pixel cell 230-R with four outlined photodiodes including photodiodes 215-7 and 215-8). In some embodiments, the first segment included in the plurality of discrete segments 240 of the light balancing structure 239 is disposed between at least two photodiodes included in the two-by-two array of four photodiodes of the optically aligned pixel cell and the proximal metal layer (e.g., the proximal metal layer 254 illustrated in FIGS. 2B and 2D). In the same or other embodiments, the first segment has a first lateral area greater than a corresponding lateral area of individual photodiodes included in the two-by-two array of four photodiodes. In the same or other embodiments, the first lateral area of the first segment is greater than a second lateral area of the second segment. In some embodiments, the lateral area of the plurality of discrete segments 240 may decrease radially as individual segments included in the plurality of discrete segments move closer to the perimeter boundary 285 of the image sensor 200. In the same or other embodiments, the amount of shifting of an individual segment included the plurality of discrete segments with respect to an optical center of the optically aligned pixel cell increases as the distance between the center of the optically aligned pixel cell and the perimeter boundary 285 of the image sensor 200 decreases.

It is appreciated that the configurations of the plurality of discrete segments 240 included in the light balancing structure 239 discussed in various embodiments of the disclosure may provide, individually or in combination, reduced asymmetric optical crosstalk for adjacent pixels or pixel cells of a common type (e.g., the second type of pixel cells, which may correspond to green pixel cells). In other words, each one of the first type of pixel cells is adjacent to two or more of the second type of pixel cells and the plurality of discrete segments 240 are configured to reduce asymmetric optical crosstalk when reading out the two or more second type of pixel cells that are adjacent to one another. More generally, it is appreciated that the plurality of discrete segments 240 has an asymmetric or non-uniform arrangement to configure the light balancing structure 239 to reduce asymmetric optical crosstalk from light propagating through the first type of pixels towards the second type of pixels.

FIG. 3A illustrates a top view (e.g., along an x-y plane based on coordinate system 399) of an image sensor 300 including a light balancing structure including a plurality of discrete segments 340, in accordance with an embodiment of the present disclosure. The image sensor 300 includes multiple instances of a two-by-two pixel cell array 390 including a red pixel cell 330-R, two green pixel cells 330-G, and one blue pixel cell 330-B. Each pixel cell included in the plurality of pixel cells 330 corresponds to a 4C pixel cell having a two-by-two array of four pixels (e.g., each green pixel cell 330-G includes four green pixels 325-G, each red pixel cell 330-R includes four red pixels 325-R, and each blue pixel cell 330-B includes four blue pixels 325-B). The light balancing structure including the plurality of discrete segments 340 (e.g., 340-1, 340-2, 340-3, 340-4, 340-5, 340-6, 340-7, 340-8, 340-9, 340-10, 340-11, 340-12, 340-13, and 340-15) is configured to mitigate asymmetric optical crosstalk. More generally, it is appreciated that the image sensor 300 is similar in many regards to the image sensor 200 illustrated in FIGS. 2A-2D and may include the same or similar features. One difference between the image sensor 300 of FIG. 3A and the image sensor 200 illustrated in FIGS. 2A-2D is the arrangement of the plurality of discrete segments. However, it is appreciated that the configuration of the plurality of discrete segments 240 included in the light balancing structure 239 illustrated in FIGS. 2A-2D may be arranged similarly to the plurality of discrete segments 340 included in the light balancing structure illustrated in FIG. 3A (or vice versa).

The plurality of discrete segments 340 included in the light balancing structure illustrated in FIG. 3A are arranged in a asymmetric or non-uniform manner, which may be based, at least in part, on the chief ray angle of an optically aligned pixel cell included in the plurality of pixel cells 330. In the illustrated embodiment, it is noted that the plurality of discrete segments closest to a perimeter boundary 385 of the image sensor 300 is arranged to extend to an edge of an optically aligned pixel cell. For example, each of the discrete segments 340-1, 340-2, 340-3, 340-4, 340-5, 340-6, 340-10, 340-11, 340-12, 340-13, 340-14, and 340-15 are positioned to laterally extend to an edge of an optically aligned one of the first type of pixel cells (e.g., red pixel cells 330-R). However, it is appreciated that elements in a common row or column may not necessarily share a common orientation. For example, discrete segments 340-11 and 340-12 are adjacent to one another and located along a common row but are oriented differently. Specifically, the discrete segment 340-11 is rotated ninety degrees relative to the discrete segment 340-12. Additionally, it is appreciated that in the illustrate embodiment, the outermost discrete segments included in the plurality of discrete segments (i.e., 340-1, 340-2, 340-3, 340-4, 340-5, 340-6, 340-10, 340-11, 340-12, 340-13, 340-14, and 340-15) each extend over only two of the pixels included in the optically aligned first type of pixel cell included in the plurality of pixel cells 230.

FIG. 3B illustrates a top view of the image sensor 300 including the light balancing structure of FIG. 3A that includes the plurality of discrete segments 340 and further including one or more dummy segments, in accordance with an embodiment of the present disclosure. It is appreciated that the configuration of the image sensor 300 illustrated in FIG. 3B may further be included in the image sensor 200 illustrated in FIG. 2A-2D. In other words, FIGS. 3A-3B show possible configurations of an image sensor that may be included in the image sensor 200, in accordance with embodiments of the present disclosure.

In some embodiments, the image sensor 300 includes a plurality of dummy segments (e.g., the plurality of dummy segments 341 and/or 342) disposed between the second side of the semiconductor substrate and the proximal metal layer (e.g., the second side 203 of the semiconductor substrate 201 and the proximal metal layer 254 illustrated in FIGS. 2A-2D). In the same or other embodiments, the plurality of dummy segments 341 and/or 342 may have a same composition and vertical placement (e.g., z-direction as indicated by coordinate system 399) within the image sensor 300 as the plurality of discrete segments 340 included in the light balancing structure of FIG. 3B. For example, in the illustrated embodiment, the plurality of discrete segments 340, the plurality of dummy segments 341, and the plurality of dummy segments 342 are arranged on a common lateral plane in accordance with the coordinate system 399. In some embodiments, individual dummy segments included in the plurality of dummy segments 341 or 342 are optically aligned with at least one of the second type of pixel cells or third type of pixel cells. For example, the plurality of dummy segments 341 are optically aligned with blue pixel cells 330-B (e.g., the third type of pixel cells) while the plurality of dummy segments 342 are optically aligned with green pixel cells 330-G (e.g., the second type of pixel cells). It is appreciated that the plurality of dummy segments 341 and/or 342 are optional in accordance with embodiments of the disclosure. In other words, either or both of the plurality of dummy segments 341 and 342 may be omitted in some embodiments of the disclosure. Rather, it is appreciated that in some embodiments, the plurality of dummy segments 341 and/or 342 may provide advantageous processing effects as reducing “dishing” that may occur during a chemical mechanical planarization step in the process of formation of the plurality of discrete segments 340.

In some embodiments, the plurality of discrete segments 340 included in the light balancing structure of FIGS. 3A and 3B has an asymmetric or non-uniform arrangement (e.g., when the size, shape, orientation, or the like of individual discrete segments are configured based on the chief ray angle of an optically aligned pixel cell included in the plurality of pixel cells 330). In the same or other embodiments, the plurality of dummy segments 341 and/or 342 may have a uniform arrangement. For example, individual dummy segments included in the plurality of dummy segments 341 are optically centered with a respective optically aligned pixel cell included in the third type of pixel cells (e.g., blue pixel cells 330-B).

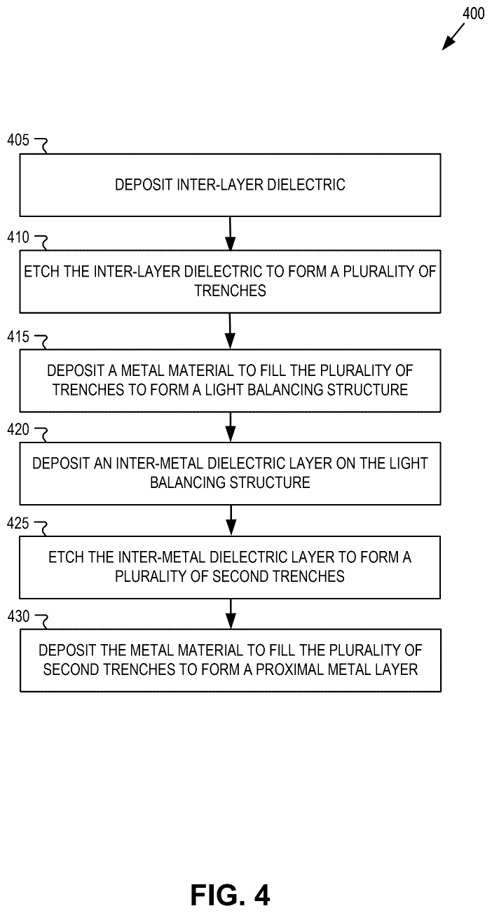

FIG. 4 illustrates an example method 400 for fabricating a light balancing structure included in an image sensor, in accordance with an embodiment of the present disclosure. The method 400 is one possible way to fabricate the light balancing structure 239 illustrated in FIGS. 2A-2D, the light balancing structure illustrated in FIGS. 3A-3B that includes the plurality of discrete segments 340, which may be included in the image sensors 200, 300, and 505. It is further appreciated that the method 400 may similarly be used to fabricate the plurality of dummy segments 341 and 342 illustrated in FIG. 3D. It is appreciated that the numbered blocks of method 400, including blocks 405, 410, 415, 420, 425, and 430, may occur in any order and even in parallel. Additionally, blocks may be repeated, added to, or removed from, the method 400 in accordance with embodiments of the present disclosure.

Embodiments of the disclosure illustrated in FIGS. 2A-3B and FIG. 5 may be fabricated using the method 400 and conventional semiconductor device processing and microfabrication techniques known by one of ordinary skill in the art. It is further appreciated that conventional semiconductor device processing and microfabrication techniques may include, but is not limited to, photolithography, ion implantation, chemical vapor deposition, physical vapor deposition, thermal evaporation, sputter deposition, reactive-ion etching, plasma etching, wafer bonding, chemical mechanical planarization, and the like. It is appreciated that the described techniques are merely demonstrative and not exhaustive and that other techniques may be utilized to fabricate one or more components of various embodiments of the disclosure.

Block 405 illustrates depositing an inter-layer dielectric (e.g., silicon dioxide) proximate to a second side of a semiconductor substrate. The semiconductor substrate may be semi-fabricated substrate and as such include a plurality of photodiodes, isolations structures, floating diffusion regions and transistors formed therein and/or thereon. A silicon dioxide layer (e.g., inter-layer dielectric 251 illustrated in FIG. 2C) may be deposited on top of the second side of the semiconductor substrate (e.g., second side 203 of the semiconductor substrate 201) via chemical vapor deposition, physical vapor deposition, thermal oxidation, or other means known by one of ordinary skill in the art. After deposition of the inter-layer dielectric, chemical mechanical planarization (CMP) may be utilized to planarize the inter-layer dielectric to form a planar surface.

Block 410 shows etching the inter-layer dielectric to form a plurality of trenches positioned over a first type of pixel cells included in a plurality of pixel cells (e.g., red pixel cells 230-R included in the plurality of pixel cells 230 of FIGS. 2A-2D). In some embodiments, each pixel cell included in the plurality of pixel cells includes one or more photodiodes disposed within the semiconductor substrate. In the same or other embodiments, the semiconductor substrate includes a first side and a second side opposite the first side (e.g., the first side 202 and the second side 203 of the semiconductor substrate 201 illustrated in FIGS. 2A-2D). The plurality of trenches may be formed using photolithography and subsequent etching. For example, a first layer of photoresist may be deposited over the inter-layer dielectric and patterned to form openings positioned over the first type of pixel cells. The plurality of trenches may then be formed using an etch (e.g., a plasma etch or other known etching technique) that removes material of the inter-layer dielectric aligned with the openings to form the plurality of trenches. It is appreciated that the first layer of photoresist may subsequently be removed after etching to form the plurality of trenches using a post-etch clean.

Block 415 illustrates depositing a metal material to fill the plurality of trenches to form a light balancing structure (e.g., the light balancing structure 239 illustrated in FIGS. 2A-2D and/or the light balancing structure formed by the plurality of discrete segments 340 illustrated in FIGS. 3A-3B). In some embodiments, a portion of the plurality of trenches may be widened to have the appropriate dimensions for the light balancing structure before deposition of the metal material. For example, a first portion of the plurality of trenches may be filled to form a via that may contact one or more components that are grounded while a second portion coupled to the first portion may form the plurality of discrete segments of the light balancing structure. It is further appreciated that the deposited metal material may, in some embodiments, include more than one material (e.g., a liner material and a fill material). In one embodiment, a liner material is first deposited into the plurality of trenches to line each trench included in the plurality of trenches. The liner material, may for example, correspond to titanium. Subsequently, the plurality of trenches lined with the liner material may be filled with a fill material (e.g., tungsten) to form the light balancing structure. In other words, in some embodiments, the light balancing structure includes a first metal (e.g., the fill material such as tungsten) at least partially surrounded by a second metal (e.g., the liner material such as titanium). In some embodiments, the light balancing structure includes a plurality of discrete segments corresponding to the plurality of trenches filled by the metal material. In the same or other embodiments, the plurality of discrete segments included in the light balancing structure are optically aligned with the first type of pixel cells included in the plurality of pixel cells to reduce asymmetric optical crosstalk that would otherwise affect a second type of pixel cells included in the plurality of pixel cells that are adjacent to the first type of pixel cells.

In some embodiments, the process of etching the inter-layer dielectric to form a plurality of trenches positioned over a first type of pixel cells included in a plurality of pixel cells (e.g., red pixel cells 230-R included in the plurality of pixel cells 230 of FIGS. 2A-2D) in block 410 further includes etching an inter-layer dielectric to form a plurality of contact trenches landing on one or more pixel components (e.g., gates of pixel transistors, the contact region of source and drain regions, and/or the contact region of floating diffusion regions). The trench width of individual trenches for the light balancing structure may be greater than the trench width of individual trenches for contacts. Subsequently, in block 415, a metal material may be deposited to fill the plurality of trenches to form the light balancing structure while simultaneously filling the plurality of contact trenches to form contacts to various pixel components. In such embodiments, plurality of trenches for light balancing structure and the plurality of contact trenches for forming contacts to pixel component can form in the same process thereby improving processing efficiency and reducing fabrication cost.

In some embodiments, chemical vapor deposition, physical vapor deposition, or other means known by one of ordinary skill in the art may be utilized to deposit the metal material. It is appreciated that additional processing may further be utilized to deposition of the metal material. The additional processes may include forming a second layer of photoresist on the inter-layer dielectric with appropriately widened openings as needed, etching to widen the plurality of trenches to form the second portion of the plurality of trenches, and etching or otherwise cleaning the inter-layer dielectric to remove the second layer of photoresist. After deposition of the metal material, chemical mechanical planarization may be utilized to planarize the light balancing structure.

Block 420 shows depositing an inter-metal dielectric layer on light balancing structure (e.g., inter-metal dielectric 253 illustrated in FIG. 2C) formed within the inter-layer dielectric. For example, a silicon dioxide layer (e.g., inter-metal dielectric 253 illustrated in FIG. 2C) may be deposited on top of the light balancing structure and the inter-layer dielectric 251 (e.g., the light balancing structure 239 and the inter-layer dielectric 251 illustrated in FIG. 2C) via chemical vapor deposition, physical vapor deposition, thermal oxidation, or other means known by one of ordinary skill in the art. After deposition of the inter-metal dielectric, chemical mechanical planarization (CMP) may be utilized to planarize the inter-metal dielectric to form a planar surface.

Block 425 illustrates etching the inter-metal dielectric layer to form a plurality of second trenches. In some embodiments, individual trenches included in the plurality of second trenches are aligned with respect to components of the image sensor (e.g., to couple pixel transistors 265 or otherwise facilitate readout of the plurality of photodiodes). It is appreciated that in some embodiments, the plurality of second trenches may be formed using photolithography and subsequent etching. For example, a third layer of photoresist may be deposited over the inter-metal dielectric and patterned to form openings positioned over or otherwise aligned with respect to components of the image sensor. The plurality of second trenches may then be formed using an etch (e.g., a plasma etch or other known etching technique) that removes material of the inter-metal dielectric aligned with the openings to form the plurality of second trenches. It is appreciated that the third layer of photoresist may subsequently be removed after etching to form the plurality of second trenches using a post-etch clean.

Block 430 shows depositing the metal material to fill the plurality of second trenches to form metal contacts of a proximal metal layer included in an interconnect stack (e.g., metal contacts M1 of the proximal metal layer 254 included in the interconnect stack 250 illustrated in FIG. 2C). In embodiments of the disclosure, the light balancing structure is disposed between the second side of the semiconductor substrate and the proximal metal layer. In some embodiments, the proximal metal layer may have a common or same composition as the light balancing structure. Thus, in some embodiments, the metal material may include the liner material and the fill material and subsequently use a similar manner of processing. In other words, formatting of the light balancing structure and the interconnect stack may be compatible and use similar processing techniques previously discussed.

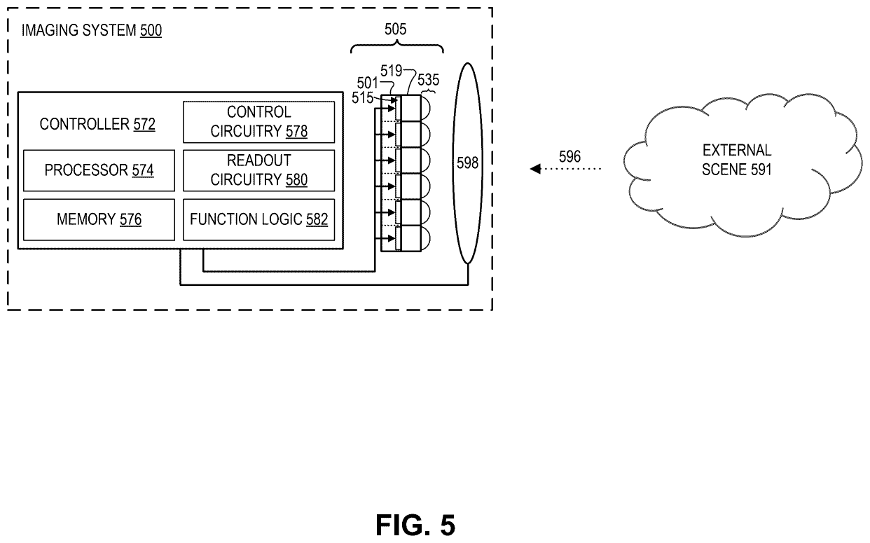

FIG. 5 is a functional block diagram of an imaging system 500 including an image sensor 505 with a light balancing structure (e.g., the light balancing structure 239 illustrated in FIGS. 2A-2D and the light balancing structure illustrated in FIGS. 3A-3B that includes the plurality of discrete segments 340) described in exemplary embodiments of FIGS. 2A-4, in accordance with embodiments of the present disclosure. The image sensor 505 can have a structure corresponding to example image sensor 200 illustrated in FIGS. 2A-2D and the image sensor 300 illustrated in FIGS. 3A-3B and may be fabricated using the method 400 illustrated in FIG. 4. For example, the image sensor 505 includes a light balancing structure to mitigate asymmetric optical crosstalk in accordance with embodiments of the disclosure. The imaging system 500 includes the image sensor 505 to generate electrical or image signals in response to incident light 596, objective lens(es) 598 with adjustable optical power to focus on one or more points of interest within the external scene 591, and controller 572 to control, inter alia, operation of the image sensor 505 and the objective lens(es) 598. The image sensor 505 is one possible implementation of example image sensor 200 illustrated in FIG. 2A-2D and the image sensor 300 illustrated in FIGS. 3A-3B. The image sensor 505 is a simplified schematic showing a semiconductor substrate 501 with a plurality of photodiodes 515 disposed within respective portions of the semiconductor substrate 501, a plurality of color filters 519, and a plurality of microlenses 535. The controller 572 includes one or more processors 574, memory 576, control circuitry 578, readout circuitry 580, and function logic 582.

The controller 572 includes logic and/or circuitry to control the operation (e.g., during pre-, post-, and in situ phases of image and/or video acquisition) of the various components of imaging system 500. The controller 572 can be implemented as hardware logic (e.g., application specific integrated circuits, field programmable gate arrays, system-on-chip, etc.), software/firmware logic executed on a general-purpose microcontroller or microprocessor, or a combination of both hardware and software/firmware logic. In one embodiment, the controller 572 includes the processor 574 coupled to memory 576 that stores instructions for execution by the controller 572, the processor 574, and/or one or more other components of the imaging system 500. The instructions, when executed, can cause the imaging system 500 to perform operations associated with the various functional modules, logic blocks, or circuitry of the imaging system 500 including any one of, or a combination of, the control circuitry 578, the readout circuitry 580, the function logic 582, image sensor 505, objective lens 598, and any other element of imaging system 500 (illustrated or otherwise). The memory is a non-transitory computer-readable medium that can include, without limitation, a volatile (e.g., RAM) or non-volatile (e.g., ROM) storage system readable by controller 572. It is further appreciated that the controller 572 can be a monolithic integrated circuit, one or more discrete interconnected electrical components, or a combination thereof, which may be formed on one or more substrates that are coupled together. Additionally, in some embodiments one or more electrical components can be coupled together to collectively function as controller 572 for orchestrating operation of the imaging system 500.

Control circuitry 578 can control operational characteristics of the array formed by the plurality of photodiodes 515 (e.g., exposure duration, when to capture digital images or videos, and the like). In some embodiments, control circuitry 578 may be configured to provide a ground reference voltage to the plurality of discrete segments including in the light balancing structure of the image sensor 505. Readout circuitry 580 reads or otherwise samples the analog signal from the individual photodiodes (e.g., read out electrical signals generated by each of the plurality of photodiodes 515 in response to incident light to generate image signals for capturing an image frame, and the like) and can include amplification circuitry, analog-to-digital (ADC) circuitry, image buffers, or otherwise. In the illustrated embodiment, readout circuitry 580 is included in controller 572, but in other embodiments readout circuitry 580 can be separate from the controller 572. Function logic 582 is coupled to the readout circuitry 580 to receive image data to de-mosaic the image data and generate one or more image frames. In some embodiments, the electrical signals and/or image data can be manipulated or otherwise processed by the function logic 582 (e.g., apply post image effects such as crop, rotate, remove red eye, adjust brightness, adjust contrast, or otherwise).

Reference throughout this specification to “one example” or “one embodiment” means that a particular feature, structure, or characteristic described in connection with the embodiment is included in at least one embodiment of the present invention. Thus, the appearances of the phrases “in one example” or “one embodiment” in various places throughout this specification are not necessarily all referring to the same embodiment. Furthermore, the particular features, structures, or characteristics can be combined in any suitable manner in one or more embodiments.

Spatially relative terms, such as “beneath,” “below,” “over,” “under,” “above,” “upper,” “top,” “bottom,” “left,” “right,” “center,” “middle,” and the like, can be used herein for ease of description to describe one element or feature's relationship relative to another element(s) or feature(s) as illustrated in the figures. It will be understood that the spatially relative terms are intended to encompass different orientations of the device in use or operation in addition to the orientation depicted in the figures. For example, if the device in the figures is rotated or turned over, elements described as “below” or “beneath” or “under” other elements or features would then be oriented “above” the other elements or features. Thus, the exemplary terms “below” and “under” can encompass both an orientation of above and below. The device can be otherwise oriented (rotated ninety degrees or at other orientations) and the spatially relative descriptors used herein are interpreted accordingly. In addition, it will also be understood that when an element is referred to as being “between” two other elements, it can be the only element between the two other elements, or one or more intervening elements can also be present.

Throughout this specification, several terms of art are used. These terms are to take on their ordinary meaning in the art from which they come, unless specifically defined herein or the context of their use would clearly suggest otherwise. It should be noted that element names and symbols can be used interchangeably through this document (e.g., Si vs. silicon); however, both have identical meaning.

The processes explained above can be implemented using software and/or hardware. The techniques described can constitute machine-executable instructions embodied within a tangible or non-transitory machine (e.g., computer) readable storage medium, that when executed by a machine (e.g., controller 550 of FIG. 5) will cause the machine to perform the operations described. Additionally, the processes can be embodied within hardware, such as an application specific integrated circuit (“ASIC”), field programmable gate array (FPGA), or otherwise.

A tangible machine-readable storage medium includes any mechanism that provides (i.e., stores) information in a non-transitory form accessible by a machine (e.g., a computer, network device, personal digital assistant, manufacturing tool, any device with a set of one or more processors, etc.). For example, a machine-readable storage medium includes recordable/non-recordable media (e.g., read only memory (ROM), random access memory (RAM), magnetic disk storage media, optical storage media, flash memory devices, etc.).

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. An image sensor, comprising:
a plurality of pixel cells arranged to form an image sensor array disposed in or on a semiconductor substrate, wherein each pixel cell included in the plurality of pixel cells includes one or more photodiodes disposed within the semiconductor substrate between a first side and a second side of the semiconductor substrate, wherein the first side is opposite of the second side;
a proximal metal layer included in an interconnect stack disposed proximate to the second side of the semiconductor substrate; and
a light balancing structure disposed between the second side of the semiconductor substrate and the proximal metal layer, wherein the light balancing structure includes a plurality of discrete segments optically aligned with a first type of pixel cells included in the plurality of pixel cells.

2. The image sensor of claim 1, wherein individual segments included in the plurality of discrete segments are coupled to ground.

3. The image sensor of claim 2, further comprising one or more transistors disposed proximate to the second side of the semiconductor substrate, wherein metal contacts disposed within the proximal metal layer are electrically coupled to the one or more transistors through one or more vias; wherein at least one of the one or more vias and at least a portion of the light balancing structure are disposed in a same dielectric layer.

4. The image sensor of claim 1, wherein the first type of pixel cells have associated chief ray angles based on a relative pixel location within the image sensor, and wherein individual segments included in the plurality of discrete segments are arranged based on the associated chief ray angles.

5. The image sensor of claim 4, wherein center-to-center distances between the individual segments included in the plurality of discrete segments and respective optically aligned pixel cells included in the first type of pixel cells are based on the associated chief ray angles.

6. The image sensor of claim 1, wherein center-to-center distances between individual segments included in the plurality of discrete segments and respective optically aligned pixel cells included in the first type of pixel cells are arranged such that the center-to-center distances increase towards a perimeter of the image sensor.

7. The image sensor of claim 1, wherein adjacent segments included in the plurality of discrete segments have at least one of different sizes, different shapes, different orientations, different lateral areas, or different positions with respect to a center of the first type of pixel cells.

8. The image sensor of claim 1, wherein the plurality of pixel cells further include a second type of pixel cells different from the first type of pixel cells, wherein each one of the first type of pixel cells is adjacent to two or more of the second type of pixel cells, and wherein the plurality of discrete segments has an asymmetric or non-uniform arrangement to configure the light balancing structure to reduce asymmetric optical crosstalk from light propagating through the first type of pixels towards the second type of pixels.

9. The image sensor of claim 8, wherein the first type of pixel cells correspond to red pixel cells and wherein the second type of pixel cells correspond to green pixel cells.

10. The image sensor of claim 1, wherein the plurality of pixel cells includes a first pixel cell, the first pixel cell including a two-by-two array of four photodiodes, and wherein a first segment included in the plurality of discrete segments is disposed between the proximal metal layer and at least two photodiodes included in the two-by-two array of four photodiodes.

11. The image sensor of claim 10, wherein the first segment has a first lateral area greater than a corresponding lateral area of individual photodiodes included in the two-by-two array of four photodiodes.

12. The image sensor of claim 1, wherein the plurality of pixel cells further includes a second type of pixel cells and a third type of pixel cells, each a different color from the first type of pixel cells, and wherein the plurality of segments included in the light balancing structure are not optically aligned with the second type of pixels cells nor the third type of pixel cells.

13. The image sensor of claim 12, further comprising a plurality of dummy segments disposed between the second side of the semiconductor substrate and the proximal metal layer, wherein individual dummy segments included in the plurality of dummy segments are optically aligned with at least one of the second type of pixel cells or the third type of pixel cells.

14. The image sensor of claim 13, wherein the plurality of discrete segments has a non-uniform arrangement and the plurality of dummy segments has a uniform arrangement, and wherein the plurality of discrete segments and the plurality of dummy segments are arranged on a common lateral plane.

15. The image sensor of claim 1, wherein the first type of pixel cells includes a first pixel cell and a second pixel cell, wherein the plurality of discrete segments includes a first segment optically aligned with the first pixel cell and a second segment optically aligned with the second pixel cell, wherein the first segment is disposed between four photodiodes included in the first pixel cell and the proximal metal layer, and wherein the second segment is disposed between two or less photodiodes included in the second pixel cell and the proximal metal layer.

16. The image sensor of claim 1, wherein the first type of pixel cells includes a first pixel cell and a second pixel cell, wherein the plurality of discrete segments includes a first segment optically aligned with the first pixel cell and a second segment optically aligned with the second pixel cell, wherein the first segment is optically centered with respect to the first pixel cell, and wherein the second segment is optically off-center with respect to the second pixel, and wherein a first chief ray angle of the first pixel cell is less than a second chief ray angle of the second pixel cell.

17. The image sensor of claim 1, wherein the proximal metal layer and the plurality of discrete segments of the light balancing structure both include a same metal material.

18. A method for forming an image sensor, comprising:
etching an inter-layer dielectric to form a plurality of trenches positioned over a first type of pixel cells included in a plurality of pixel cells, wherein each pixel cell included in the plurality of pixel cells includes one or more photodiodes disposed within a semiconductor substrate, the semiconductor substrate including a first side and a second side opposite the first side;
depositing a metal material to fill the plurality of trenches to form a light balancing structure, wherein the light balancing structure includes a plurality of discrete segments corresponding to the plurality of trenches filled by the metal material, the plurality of discrete segments optically aligned with the first type of pixel cells included in the plurality of pixel cells;
depositing an inter-metal dielectric layer on the light balancing structure formed within the inter-layer dielectric;
etching the inter-metal dielectric layer to form a plurality of second trenches; and
depositing the metal material to fill the plurality of second trenches to form a proximal metal layer included in an interconnect stack, wherein the light balancing structure is disposed between the second side of the semiconductor substrate and the proximal metal layer.

19. A multi-color image pixel, comprising:
a group of four pixel cells arranged in a two-by-two array, the group of four pixel cells including a red pixel cell, two green pixel cells adjacent to the red pixel cell, and a blue pixel cell adjacent to the two green pixel cells, and wherein each pixel cell included in the group of four pixel cells includes at least four photodiodes disposed within a semiconductor substrate;
a proximal metal layer included in an interconnect stack coupled to the semiconductor substrate; and
a discrete segment of a light balancing structure optically aligned with the red pixel cell included in the group of four pixel cells, wherein the discrete segment is further disposed between the semiconductor substrate and the proximal metal layer.

20. The multi-color image pixel of claim 19, wherein the multi-color image pixel is included in an image sensor, wherein the discrete segment is adapted to mitigate asymmetric optical crosstalk for the two green pixel cells by positioning the discrete segment over the red pixel cell based, at least in part, on a relative location of the red pixel cell in a pixel array of the image sensor.
